(19) United States
(12) Patent Application Publication
(10) Pub. No.: US 2013/0003477 A1
(43) Pub. Date: Jan. 3, 2013

(54) SEMICONDUCTOR MEMORY DEVICE INCLUDING SPARE ANTIFUSE ARRAY AND ANTIFUSE REPAIR METHOD OF THE SEMICONDUCTOR MEMORY DEVICE

(76) Inventors: Ju-Seop PARK, Seongnam-si (KR); Sin Ho KIM, Suwon-si (KR); Byung-Sik MOON, Seoul (KR); Jong-Pil SON, Seongnam-si (KR); Jin-Ho KIM, Uiwang-si (KR); Hyoung-Joo KIM, Seongnam-si (KR); Jong-Min OH, Seoul (KR); Seong-Jin JANG, Seongnam-si (KR)

(21) Appl. No.: 13/534,161

(22) Filed: Jun. 27, 2012

(30) Foreign Application Priority Data
Jun. 30, 2011 (KR) 10-2011-0064611

(51) Int. Cl. G11C 11/21; G11C 29/44

(52) U.S. Cl. 365/200

(57) ABSTRACT

A semiconductor memory device including an antifuse cell array and a spare antifuse cell array are provided. An antifuse cell array includes a first set of antifuse cells arranged in a first direction and each one of the first set of antifuse cells is connected to a corresponding one of first through nth word lines. The spare antifuse cell array includes a first spare set of antifuse cells arranged in the first direction and each one of the first spare set of antifuse cells is connected to a corresponding one of first through kth spare word lines. A first operation control circuit is configured to program antifuses of the antifuse cell array and the spare antifuse cell array, and to read a status of each of the antifuses. The first operation control circuit is commonly connected to the first set of antifuse cells and the first spare set of antifuse cells.

### CROSS-REFERENCE TO RELATED APPLICATIONS

This U.S. non-provisional patent application claims priority under 35 U.S.C. §119 of Korean Patent Application No. 10-2011-0064611, filed on Jun. 30, 2011, in the Korean Intellectual Property Office (KIPO), the entire contents of which are hereby incorporated by reference.

### BACKGROUND

Example embodiments relate to semiconductor devices, and more particularly, to a semiconductor memory device including a spare antifuse cell array, and an antifuse repair method of the semiconductor memory device.

To store specific information or perform a repair function, an antifuse having an opposite electrical characteristic to a conventional fuse may be used.

Since an antifuse has an advantage that it can be programmed even at a package level, it has been widely adopted in a semiconductor memory device such as a dynamic random access memory (DRAM).

If unintended defects occur in an antifuse of an antifuse cell, it may be difficult for an antifuse cell array including a plurality of antifuse cells disposed in a matrix form including rows and columns to be used for a wanted purpose. The defects of an antifuse may occur in the process of manufacturing an antifuse or programming an antifuse. In the case that an antifuse ruptures in the process of programming the antifuse, since information read from an antifuse may be different from information programmed in an antifuse, an intrinsic function of an antifuse may be lost.

### SUMMARY

Some example embodiments provide a semiconductor memory device.

According to one example embodiment, a semiconductor memory device may include an antifuse cell array, a spare antifuse cell array, and a first operation control circuit. The antifuse cell array includes a first set of antifuse cells arranged in a first direction and each one of the first set of antifuse cells is connected to a corresponding one of first through nth word lines, n is a natural number and greater than 1. The spare antifuse cell array includes a first spare set of antifuse cells arranged in the first direction and each one of the first spare set of antifuse cells is connected to a corresponding one of first through kth spare word lines, k is a natural number. The first operation control circuit is configured to program antifuses of the antifuse cell array and the spare antifuse cell array, and configured to read a status of each of the antifuses. The first operation control circuit is commonly connected to the first set of antifuse cells and the first spare set of antifuse cells.

According to another example embodiment, a semiconductor memory device includes a first antifuse cell array, a second antifuse cell array, a first program circuit, and a first read circuit. The first antifuse cell array includes a first plurality of antifuse cells configured to store data and the first plurality of antifuse cells are disposed in a first direction and a second direction perpendicular to the first direction. The second antifuse cell array includes a second plurality of antifuse cells configured to repair a defect data of the first plurality of antifuse cells and the second plurality of antifuse cells are disposed in the first direction and the second direction. The first program circuit is configured to program at least one antifuse of each of the first and second plurality of antifuse cells. The first read circuit is configured to read a status of at least one antifuse of each of the first and second plurality of antifuse cells. The first program circuit and the first read circuit are commonly connected to at least one cell of the first plurality of antifuse cells and at least one cell of the second plurality of antifuse cells.

According to further example embodiment, an antifuse repair method of a semiconductor memory device is disclosed. The method includes providing a first antifuse array including a first plurality of antifuses arranged in a first direction and sharing an operation control circuit, and the first plurality of antifuses connecting first through nth word lines. Each one of the first through nth word lines extending in a second direction perpendicular to the first direction, wherein n is a natural number and greater than 1. The method further includes providing a second antifuse array including a second plurality of antifuses sharing a spare word line in the second direction and sharing the operation control circuit in the first direction with the first plurality of antifuses. The method further includes providing a third antifuse array for storing defect information of antifuses of the first antifuse array and comparing a row address being applied to the information stored in the third antifuse array. The method further includes inactivating a word line of a failed antifuse of the first plurality of antifuses and activating a spare word line of antifuse of the second plurality of antifuses when the row address coincides with the information stored in the third antifuse array.

### BRIEF DESCRIPTION OF THE FIGURES

Various example embodiments will be described below in more detail with reference to the accompanying drawings.

FIG. 1 is a block diagram of an antifuse cell array repair device applied to a semiconductor memory device according to example embodiments.

FIG. 2 is a view illustrating a detailed connection between an antifuse cell array and a spare antifuse cell array sharing with an operation control circuit illustrated in FIG. 1 according to certain example embodiments.

FIG. 3 is a circuit diagram illustrating operations at each mode of an antifuse and a spare antifuse illustrated in FIG. 2 according to certain example embodiments.

FIG. 4 is a flow chart illustrating a flow of program operation of a fail antifuse cell array illustrated in FIG. 1 according to certain example embodiments.

FIG. 5 is a flow chart illustrating a flow of repair operation of an antifuse cell array repair device of FIG. 1 according to certain example embodiments.

FIG. 6 is a drawing for describing a repair of word line unit according to example embodiments.

FIG. 7 is a drawing for describing a repair of block unit according to example embodiments.

FIG. 8 is a block diagram illustrating an example embodiment of a first application in an electronic system.

FIG. 9 is a block diagram illustrating an example embodiment of a second application in a data processing device.

FIG. 10 is a block diagram illustrating an example embodiment of a third application in a memory card.

FIG. 11 is a block diagram illustrating an example embodiment of a fourth application in a portable terminal.

### DETAILED DESCRIPTION OF THE EMBODIMENTS

Various example embodiments will be described more fully hereinafter with reference to the accompanying drawings, in which some example embodiments are shown. This inventive concept may, however, be embodied in many different forms and should not be construed as limited to the embodiments set forth herein. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms such as “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

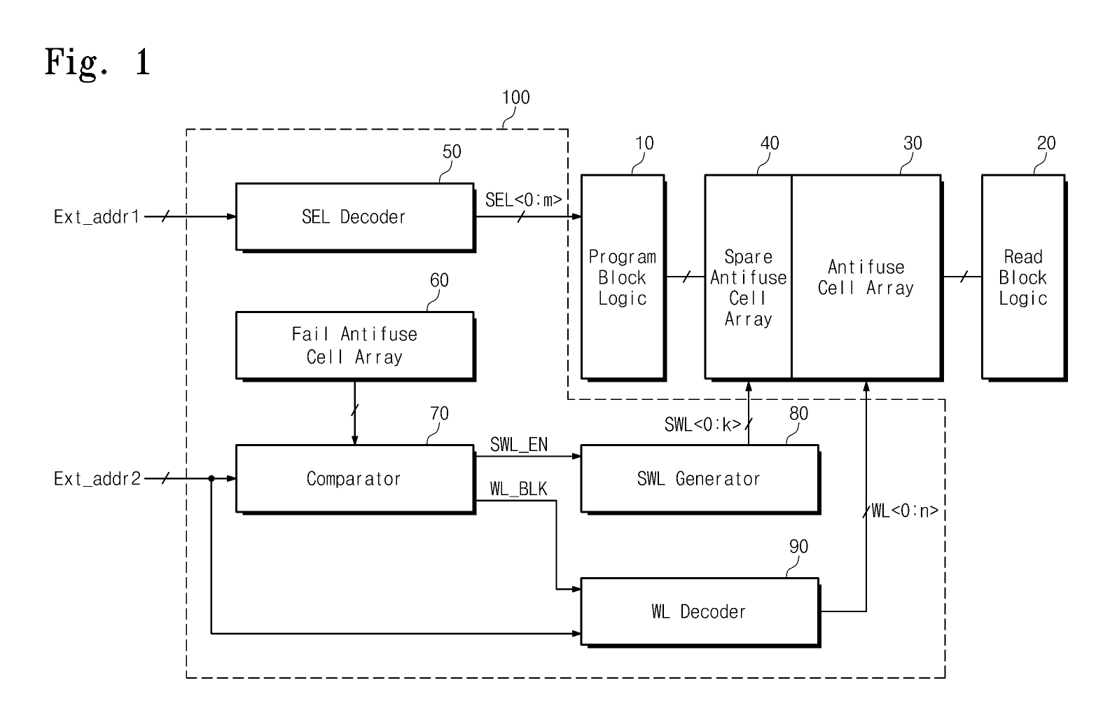

FIG. 1 is a block diagram of an antifuse cell array repair device applied to a semiconductor memory device in accordance with example embodiments.

Referring to FIG. 1, an antifuse cell array repair device may include an antifuse cell array 30, a spare antifuse cell array 40, a program block logic 10 and a read block logic 20. The antifuse array repair device may also include a repair control circuit 100 (also referred to generally herein as an “operation control circuit”) including a fail antifuse cell array 60. As illustrated in FIG. 1, the repair control circuit 100 may include a select decoder 50, a fail antifuse cell array 60, a comparator 70, a spare word line generator 80 and a word line decoder 90.

In the case of programming defect information of the antifuse cell array in a word line unit, the fail antifuse cell array 60 may be a fail word line antifuse cell array to store defect information of word line units with respect to antifuses of the antifuse cell array 30 and operation information about a semiconductor memory device.

The repair control circuit 100 disables a word line WL of failed antifuses and enables a spare word line SWL of spare antifuses when a row address Ext_addr2 being applied and information stored in the fail word line antifuse cell array 60 coincide.

When defects occur in antifuses of the antifuse cell array 30, a failed antifuse is repaired with a spare antifuse of the spare antifuse cell array 40. For example, a repair scheme of an individual fuse unit, a word line unit, or a block unit including two or more word lines may be adopted. When sharing an operation control circuit for programming or reading the antifuse cell array 30, a repair circuit constitution for a repair of antifuse becomes compact. Also, if using or applying an antifuse repair scheme, an antifuse ruptured during a program process may be substituted with a spare antifuse. Also, since storage information of an antifuse can be changed when necessary even though defects do not occur in the antifuse, information about a data access operation of semiconductor memory, an input/output operation or all kinds of characteristic controls may be changed.

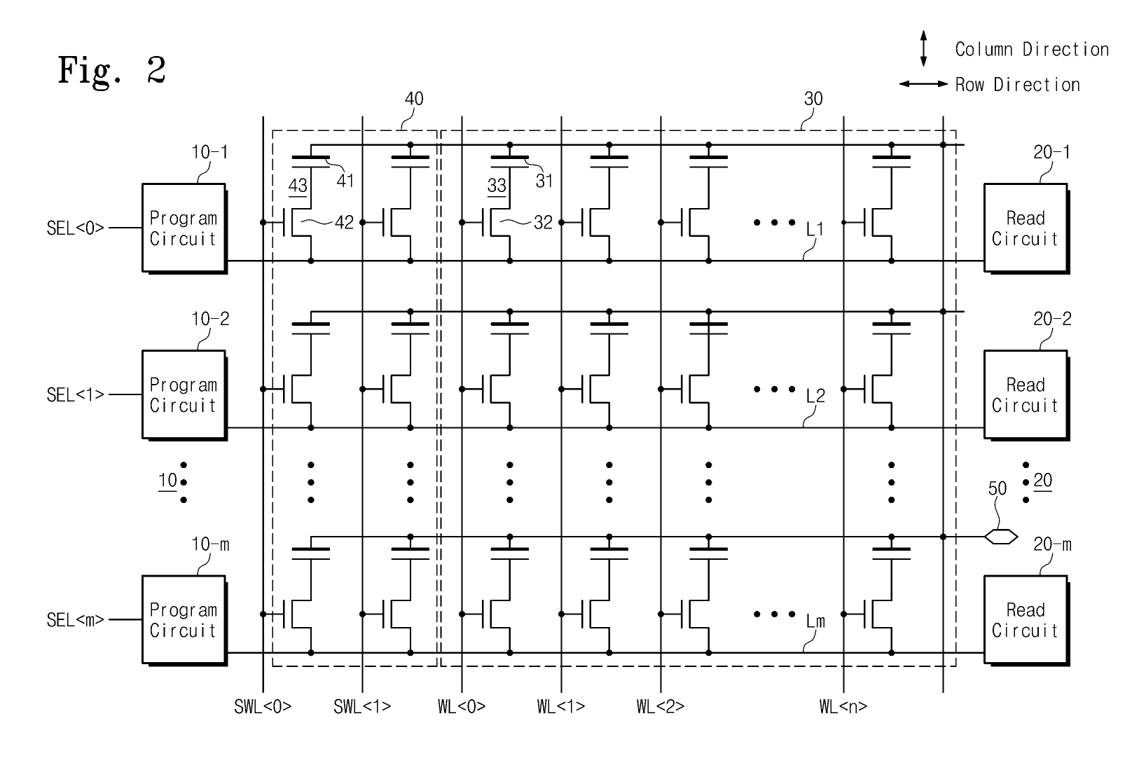

FIG. 2 is a view illustrating a detailed connection between an antifuse cell array and a spare antifuse cell array sharing an operation control circuit such as illustrated in FIG. 1 according to certain example embodiments.

Referring to FIG. 2, the spare antifuse cell array 40 is disposed to be adjacent to the antifuse cell array 30 representing a normal (i.e., default) antifuse cell array. Antifuse cell 33, for example, may include one antifuse 31 and one access transistor 32. The antifuse cell 33 may be repeated in a first direction and a second direction perpendicular to the first direction in the antifuse cell array 30. A plurality of antifuse cells sharing an operation control circuit along the first direction (e.g., a row direction) are arranged in the antifuse cell array 30. In FIG. 2, since a first program circuit 10-1 and a first read circuit 20-1 are connected to a first common line L1, a second program circuit 10-2 and a second read circuit 20-2 are connected to a second common line L2 and a mth program circuit 10-m and a mth read circuit 20-m are connected to a mth common line Lm, m quantity of operation control circuits are disposed along the second direction (e.g., a column direction).

Spare antifuse cell 43 may include one antifuse 41 and one access transistor 42. The spare antifuse cell 43 may be repeated in the first direction and the second direction in the spare antifuse cell array 40. One or more spare antifuse cells may share a spare word line SWL along the second direction and one or more spare antifuse cells may share the operation control circuit with the one or more antifuse cells along the first direction.

The operation control circuit in FIG. 1 may include the program block logic 10 to permanently program fuses selected from the antifuse cell array 30 and the spare antifuse cell array 40 and the read block logic 20 to read storage information of the fuses programmed by the program block logic 10. The program block logic 10 may include the plurality of program blocks 10-1˜10-m illustrated in FIG. 2. The read block logic 20 may include the plurality of read blocks 20-1˜20-m illustrated in FIG. 2. Herein, m is a natural number of two or more.

As illustrated in FIG. 2, if the spare antifuse cell array 40 is disposed to be adjacent to the antifuse cell array 30, since the one or more spare antifuse cells may share the operation control circuit with the one or more antifuse cells along a row direction, it is not necessary to prepare an additional operation control circuit for driving the one or more spare antifuse cells of the spare antifuse cell array 40. Thus, since a realized circuit constitution becomes simple while performing a repair operation of antifuses, an increase of chip size may be effectively suppressed. When newly programming information about an operation of a semiconductor memory device in the spare antifuse cell 43, an operation of the semiconductor memory device may be changed depending on information programmed in the spare antifuses 43.

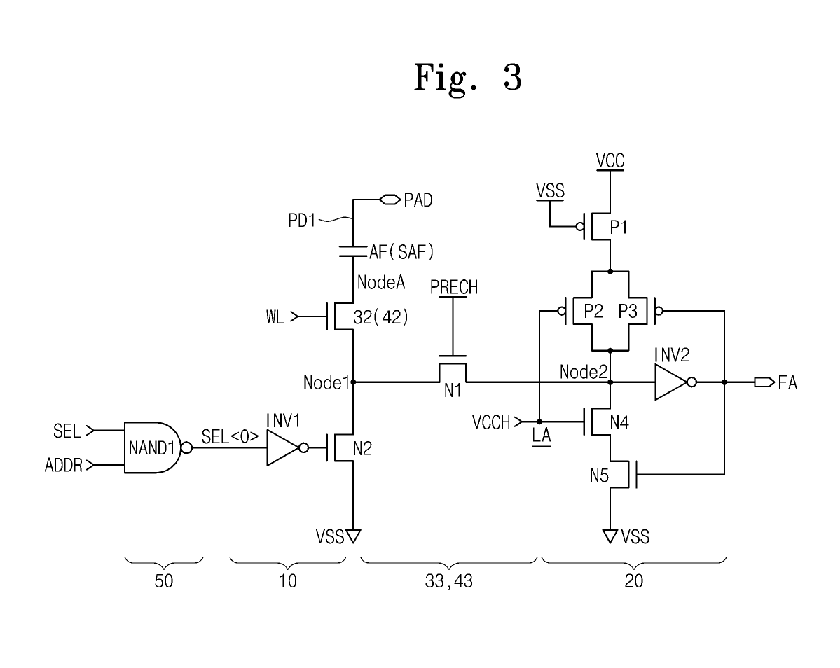

As shown in FIG. 2, a unit cell constituting the spare antifuse cell 43 is comprised of one antifuse 41 and one access transistor 42 but the unit cell may be embodied by a plurality of elements as illustrated in FIG. 3. Also, as shown in FIG. 2, a unit cell constituting the antifuse cell 33 is comprised of one antifuse 31 and one access transistor 32 but the unit cell may be embodied by a plurality of elements as illustrated in FIG. 3.

FIG. 3 is a circuit diagram illustrating operations at each mode of an antifuse and a spare antifuse illustrated in FIG. 2 according to certain example embodiments.

In FIG. 3, a part of the select decoder 50, a part of the program block logic 10 and a part of the read block logic 20 illustrated in FIG. 1 are illustrated together with the unit cell.

Referring to FIG. 3, one end of an antifuse AF is connected to a node PD1 of a pad PAD and the other end of the antifuse AF is connected to a node A with an access transistor 32. A gate of the access transistor 32 is connected to a word line. When the antifuse AF is adopted in the spare antifuse cell array 40, the antifuse AF functions as a spare antifuse SAF.

The repair method using the antifuse AF may overcome a limitation of a repair method using a conventional fuse. For example, since a repair method using a conventional fuse is performed in a wafer level, a repair work fails if a failed cell exists in a package level of a semiconductor memory device. A limit of that fuse method may be overcome by performing a repair using an antifuse. The antifuse has an electrical characteristic opposite to a general fuse so that it is programmed to repair a failed cell in a package level.

An antifuse is generally a resistive fuse device. The antifuse may have a high resistance (for example, 100 MΩ) when it is not programmed and may have a low resistance (for example, less than 100 kΩ) after a program operation is performed on the antifuse. The antifuse may be constituted by a very thin dielectric material having a thickness of several to several hundreds of angstroms such that a dielectric substance such as silicon dioxide SiO2, silicon nitride, tantalum oxide, or silicon dioxide-silicon nitride-silicon dioxide is interposed between two conductors.

A program operation of antifuse is performed by applying a high voltage (for example, 6V-10V) to the antifuse through antifuse terminals for a sufficient time to destruct a dielectric substance between two conductors. Thus, if an antifuse is programmed, conductors at both ends of the antifuse are shorted and thereby a resistance is lowered. A basic state of antifuse is electrically opened and if the antifuse is programmed by applying a high voltage to the antifuse, a state of the antifuse is electrically shorted.

In FIG. 3, an antifuse cell including the antifuse AF and the access transistor 32 may further include NMOS transistors N1 and N2.

A NAND gate NAND1 may be included in the select decoder 50 of FIG. 1 and an inverter INV1 may be included in the program block logic 10. Also, a latch portion LA including PMOS transistors P1, P2 and P3, NMOS transistors N4 and N5 and an inverter INV2 may be included in the read block logic 20 of FIG. 1.

The NMOS transistor N1 functioning as a switching device switches between the fuse node Node1 and a latch node Node2 in response to a control signal PRECH. The control signal PRECH may be generated using a power supply voltage Vcc. The fuse node Node1 may be a common node connected to a plurality of antifuse cells.

During a program operation of the antifuse AF, the control signal PRECH increases as a power supply voltage Vcc increases at the beginning of when a power is applied. When the power supply voltage Vcc reaches a specific level to maintain the specific level, the control signal PRECH is maintained at the same level as the power supply voltage Vcc only for a predetermined time. Also, during a read operation of the antifuse AF, the control signal PRECH is maintained at a “high” level for a predetermined time.

Thus, if a power supply voltage Vcc is applied, the control signal PRECH rises to maintain a specific level for a predetermined time and thereby a current may flow from a latch node Node2 to a fuse node Node1.

When a failed antifuse is checked in a test mode of semiconductor memory device, a program mode select signal SEL is activated to repair the failed antifuse. The program mode select signal SEL may be concurrently provided to a plurality of antifuses AF so that programs are concurrently performed on a plurality of antifuses AF. The program mode select signal SEL may be provided by a test mode register set TMRS.

An address signal ADDR may be selectively activated. That is, although the program mode select signal SEL may be activated when a program operation is performed to be applied to all the antifuses AF in some embodiments, the address signal ADDR is activated only on an antifuse to be programmed among a plurality of antifuses AF. In one embodiment, it is assumed that an activated signal has a logic “high level”.

For example, when programming the antifuse AF, the NMOS transistor N1 maintains a turn-off state. The NAND gate NAND1 outputs a signal having “low level” in response to the program mode select signal SEL having “high level” and the address signal ADDR having “high level”. The signal having “low level” passes through the inverter INV1 to be converted into a signal having “high level”. The signal having “high level” is applied to a gate terminal of the NMOS transistor N2. The NMOS transistor N2 is turned on in response to the signal having “high level”.

In FIG. 3, one antifuse AF is illustrated to be connected to the pad PAD to which a high voltage is applied. However, a plurality of antifuses AF may be connected to the pad PAD. If a high voltage is applied to the pad PAD, the high voltage is applied to first ends PD1 of all the antifuses AF. Since the NMOS transistor N2 is turned on by the program mode select signal SEL and the address ADDR and the access transistor 32 is turned on by applying a “high” voltage to a gate of the access transistor 32, the fuse node Node1 becomes a ground voltage Vss. As a result, a high voltage is applied to both ends of the antifuse AF to rupture a dielectric substance of the antifuse AF and thereby a program operation of the antifuse AF is achieved.

When not programming the antifuse AF, the NAND gate NAND1 outputs a signal of “high level” in response to the program mode select signal SEL having “high level” and the address signal ADDR having “low level”. The signal having “high level” passes through the inverter INV1 to be converted into a signal having “low level”. The signal having “low level” is applied to a gate terminal of the NMOS transistor N2. The NMOS transistor N2 is turned off in response to the signal having “low level”.

Since the NMOS transistor N2 is turned off, a dielectric substance of the antifuse AF is not ruptured and thereby a program on an antifuse not selected is performed.

Although a high voltage is applied to the pad PAD when a program operation is performed, a ground voltage Vss may be applied to the pad PAD in the case that a program operation is not performed.

In one embodiment, an NMOS transistor (not shown) may be connected between the fuse node Node1 and the access transistor 32 functions as a circuit protection device. That is, since if a high voltage is applied to the pad PAD when a program operation is performed, a gate oxide layer of each of the transistors constituting a circuit is damaged, there is a need to prevent that damage.

In one embodiment, when the antifuse AF is programmed, a read operation of the antifuse AF is as follows. The latch portion LA precharges the latch node Node2 and latches a voltage of the latch node Node2 in response to the power supply voltage Vcc. The latch portion LA precharges the latch node Node2 as the power supply voltage Vcc rises at the beginning of when a power is applied to a semiconductor device. A power supply stable signal VCCH is maintained at a low level while the power supply voltage Vcc rises, and VCCH transits to a “high level” when the power supply voltage reaches a specific level. Since the power supply stable signal VCCH is at “low level” at the beginning of when a power is applied, a current path is formed through the PMOS transistor P1 and the PMOS transistor P2. Since a control signal PRECH rises as the power supply voltage Vcc rises, a current flows to the fuse node Node1 through the PMOS transistor P1, the PMOS transistor P2 and the NMOS transistor N1. Also, the current flows to the pad node PD1 through the antifuse AF. In this case, since the programmed antifuse AF has a relatively low resistance, a voltage of the fuse node Node1 descends to become a low level.

While the control signal PRECH is maintained at a high level, a voltage of the latch node Node2 also descends depending on a voltage of the fuse node Node1. If a level of the power supply voltage Vcc becomes more than a predetermined level, the power supply stable voltage VCCH transits from a low level to a high level. Thus, the PMOS transistor P2 is turned off and the NMOS transistor N4 is turned on. If a voltage of the latch node Node2 descends to become a low level, the inverter INV2 outputs a signal of high level. The NMOS transistor N5 is turned on and the PMOS transistor P3 is turned off and thereby a voltage of the latch node Node2 is latched to be a low level. When the antifuse AF is programmed, a fuse signal FA may be read to be a high level.

For example, when the antifuse AF is not programmed, since a resistance of the antifuse AF is relative great, it is difficult that a current flowing through the fuse node Node1 flows to the pad PAD through the antifuse AF. As a voltage of the fuse node Node1 rises, a voltage of the latch node Node2 may also rise. If the power supply stable signal VCCH transits to a high level, the PMOS P2 is turned off and the NMOS transistor N4 is turned on. If a voltage of the latch node Node2 rises to be a high level, the inverter INV2 outputs a low level signal. The NMOS transistor N5 is turned off and the PMOS transistor P3 is turned on and thereby a voltage of the latch node Node2 is latched to be a high level. Although the NMOS transistor N1 is turned off, the high level may maintain a latch state. Thus, in the case that the antifuse AF is not programmed, a fuse signal FA may be read to be a low level.

Although a program operation of an antifuse or a spare antifuse and a read operation after programming and not programming the antifuse or the spare antifusing are described, that is only an illustration. A program operation and a read operation may be differently performed through a different circuit constitution.

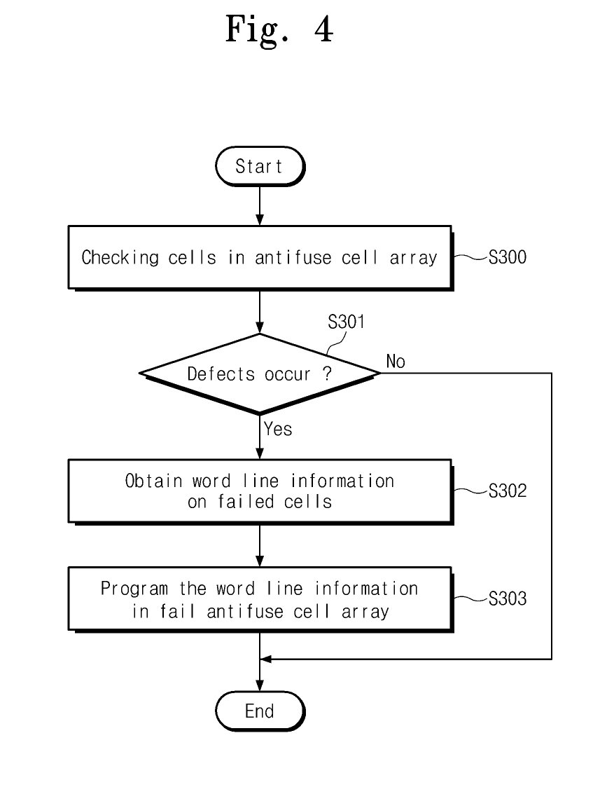

FIG. 4 is a flow chart illustrating a flow of program operation of a fail antifuse cell array illustrated in FIG. 1 according to certain example embodiments.

Referring to FIG. 4, in a step of S300, checking the antifuse cells 33 in the antifuse cell array 30 is performed to repair the antifuse. The check may be performed after the antifuse cells are manufactured or after the antifuse cells are programmed after being manufactured.

In a step of S301, it is checked whether defects occur or not. If defects occur in the step of S301, in a step of S302, word line information of failed antifuse cells is obtained. For example, in FIG. 2, if it is checked that defects occur in the antifuse cells 33 connected to the first word line WL<0>, the obtained word line information becomes the first word line WL<0>.

The obtained word line information is programmed in the fail antifuse cell array 60 of FIG. 1 in a step of S303. The fail antifuse cell array 60 may store not only the word line information on the failed antifuses but also additional information regarding, for example, a data access operation of semiconductor memory device, an input/output operation, or all kinds of characteristic controls.

Also, word line information may be programmed when performing a repair by a word line unit, and the fail antifuse cell array 60 may store individual information about individual cells or individual word lines of antifuses or block information including two or more word lines of antifuses.

The fail antifuse cell array 60 may include a number of antifuses that can distinguish word lines that exist in the spare antifuse cell array 40 when repairing word lines and additionally may include antifuses storing tag information representing whether a repair is performed or not.

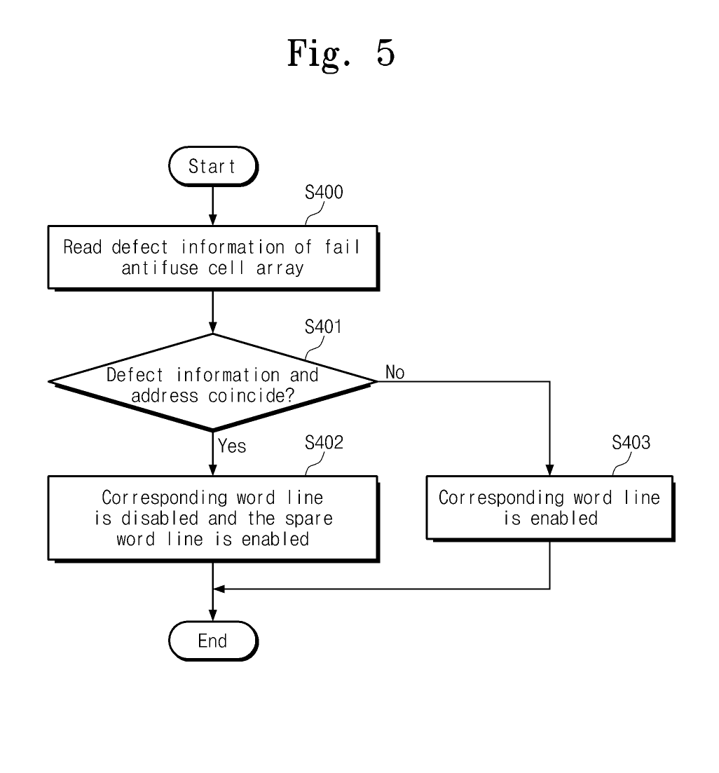

FIG. 5 is a flow chart illustrating a flow of repair operation of an antifuse cell array repair device of FIG. 1 according to certain example embodiments.

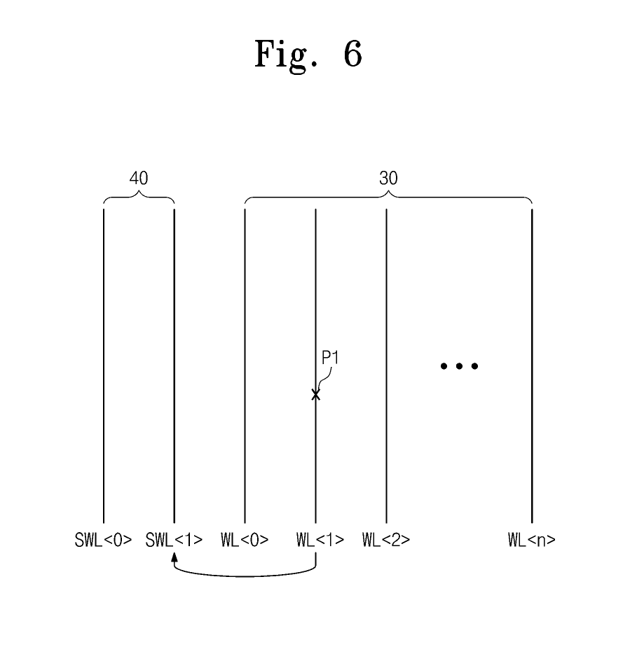

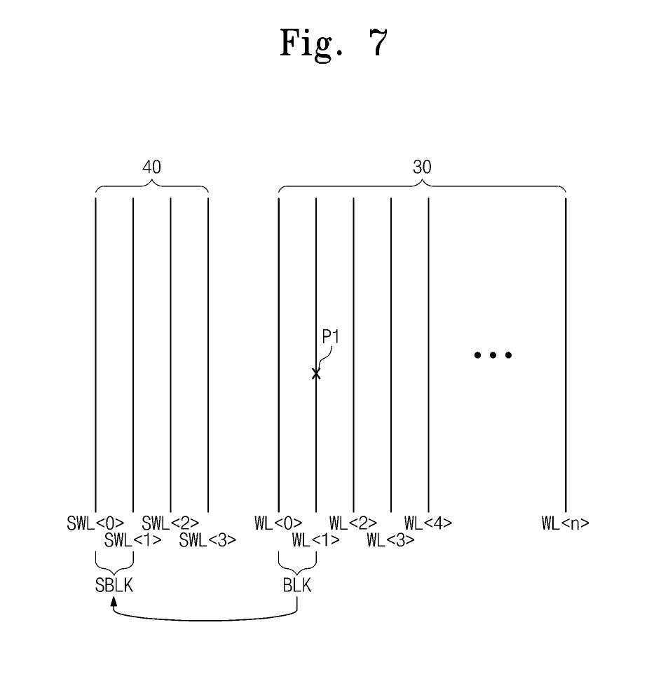

FIG. 6 is a drawing for describing a repair of a word line unit according to example embodiments. FIG. 7 is a drawing for describing a repair of block unit including word lines according to example embodiments.

Referring to FIG. 5, when repair operations of antifuses are performed, in a step of S400, program information stored in the fail antifuse cell array 60 is read. For example, the fail antifuse cell array 60 that programs defect information of the antifuses may provide defect information to the comparator 70 of FIG. 1 to realize a repair operation. The program information stored in the fail antifuse cell array 60 is read before an access operation is performed on the antifuse cell array 30.

For example, the comparator 70 shown in FIG. 1 may receive the second external address Ext_addr2. The second external address Ext_addr2 may be A10-A12 when the first external address Ext_addr1 is A0-A9. However, in some cases, the second external address Ext_addr2 may be the same as the first external address Ext_addr1.

In a step of S401, it is checked whether or not the defect information and the second external address Ext_addr2 coincide. If those do not coincide, the repair operation is not performed and in a step of S403, a selected word line of the antifuse cell array 30 is enabled.

The step of S401 may be performed by the comparator 70 of FIG. 1. An internal circuit of the comparator 70 may be comprised of exclusive-or gates. For instance, in the case that a signal of the address A10-A12 is 101, if the read defect information is also 101, the comparator 70 activates a spare word line enable signal SWL_EN for enabling a spare word line of the spare antifuse cell array 40. Also, the comparator 70 activates a normal word line blocking signal WL_BLK for blocking a normal word line of the antifuse cell array 30.

As such, in a step of S402, the comparator 70 activates the spare word line enable signal SWL_EN to provide the activated spare word line enable signal SWL_EN to the spare word line generator 80. The comparator 70 activates the normal word line blocking signal WL_BLK to provide the activated normal word line blocking signal WL_BLK to the word line decoder 90. Thus, the word line connected to the failed antifuse in the antifuse cell array 30 is disabled and the spare word line SWL connected to a spare antifuse in the spare antifuse cell array 40 is enabled. As a result, a repair operation on the failed antifuse is performed by a word line unit.

In the step of S403, the comparator 70 inactivates the spare word line enable signal SWL_EN to provide the inactivated spare word line enable signal SWL_EN to the spare word line generator 80. Also, the comparator 70 inactivates the normal word line blocking signal WL_BLK to provide the inactivated normal word line blocking signal WL_BLK to the word line decoder 90. Thus, the spare word line SWL being enabled in the spare antifuse cell array 40 does not exist. The word line decoder 90 for decoding a word line in the antifuse cell array 30 decodes the second external address Ext_addr2 to enable the corresponding normal word line WL when the normal word line blocking signal WL_BLK is inactivated.

Since the antifuse using phenomenon of gate oxide breakdown may be used as a nonvolatile memory, it may be used in a DRAM and various integrated circuits to increase flexibility. For instance, when the antifuse is applied in a redundancy scheme for repairing a memory cell of DRAM, yield may be improved. Also, if applying the antifuse, a voltage level of DC circuit may be precisely controlled and information which relates to a DRAM operation may be stored in the antifuse.

Referring to FIG. 6, in one embodiment, if a failed antifuse exists at a point P1 in the antifuse cell array 30, the second normal word line WL<1> of the antifuse cell array 30 is repaired with the second spare word line SWL<1> of the spare antifuse cell array 40. In the case that an address pointing the second normal word line WL<1> is applied, the second normal word line WL<1> is disabled and the second spare word line SWL<1> is enabled.

Referring to FIG. 7, in one embodiment, if a failed antifuse exists at a point P1 in the antifuse cell array 30, a block BLK of the antifuse cell array 30 is repaired with a spare block SBLK of the spare antifuse cell array 40. The block BLK is antifuses connected to the first normal word line WL<0> and the second normal word line WL<1>. In the case that an address pointing a specific block is applied, a normal block is disabled and a spare block is enabled. As such, a set of word lines disabled according to the methods described above can include a single word line or a group of word lines, for example, that constitute a block.

Although a repair is performed in a column direction in the present embodiment, the repair may be performed in a row direction.

To perform an antifuse repair of semiconductor memory device, an antifuse cell array including antifuses sharing an operation control circuit in a first direction and a spare antifuse cell array including spare antifuses sharing the operation control circuit with the antifuses in the first direction while sharing a spare word line in a second direction crossing the first direction are provided. Also, a fail word line antifuse cell array to store defect information of word line units on antifuses of the antifuse cell array is provided.

After providing the antifuse cell array and the spare antifuse cell array, a row address being applied is compared with information stored in the fail word line antifuse cell array. If those are coincide with each other, a repair of antifuse may be performed by a word line unit by inactivating a word line of failed antifuses and activating the set spare word line of spare antifuses.

Information on an operation of semiconductor memory device may be stored in the fail antifuse cell array. In one embodiment, the semiconductor memory device may be a dynamic random access memory including a mode register set circuit setting an operation mode for programming an antifuse cell array.

According to a repair method of the embodiments, a failed antifuse is substituted with a spare antifuse. A ruptured antifuse during a program may be substituted with a spare antifuse not ruptured. That is, a read only data of antifuse once it is programmed may be changed to a different data.

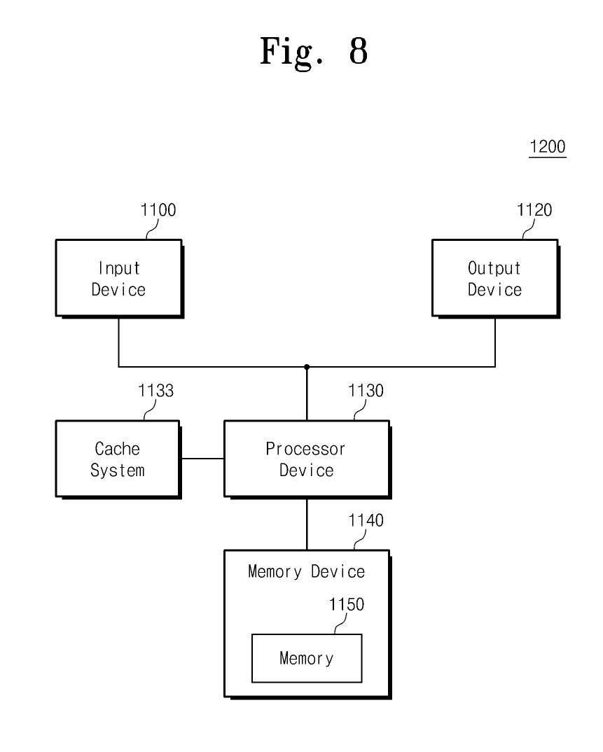

FIG. 8 is a block diagram illustrating an example embodiment of a first application in an electronic system.

Referring to FIG. 8, an electronic system 1200 includes an input device 1100, an output device 1120, a processor device 1130, a cache system 1133 and a memory device 1140.

In FIG. 8, the memory device 1140 may include a DRAM memory 1150 including a spare antifuse cell array. The processor device 1130 controls the input device 1100, the output device 1120 and the memory device 1140 through respective interfaces. In FIG. 8, if the processor device 1130 applies the DRAM memory 1150 adopting the antifuse cell array repair device like FIG. 1, a data input/output operation of the DRAM memory 1150 may be changed. Even though adopting the spare antifuse cell array, a chip size of the DRAM memory 1150 is not greatly increased by using the operation control circuit in common. Thus, total performance of electronic system adopting the DRAM memory 1150 may be improved.

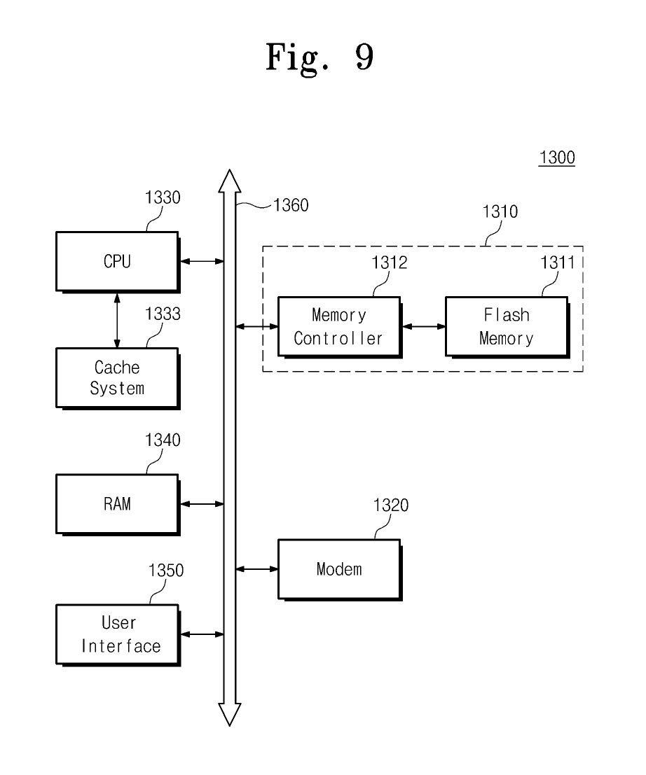

FIG. 9 is a block diagram illustrating an example embodiment of a second application in a data processing device. Referring to FIG. 9, a RAM 1340 including the antifuse cell array repair device in accordance with some embodiments of the inventive concept may be built in a data processing device such as a mobile device or a desk top computer. In FIG. 9, if the data processing device 1300 applies the RAM 1340 adopting the antifuse cell array repair device of FIG. 1, a data input/output operation of the RAM 1340 may be selectively changed. Similarly, even though adopting the spare antifuse cell array, a chip size of the RAM 1340 is not greatly increased by using the operation control circuit in common. Thus, total performance of data processing device adopting the RAM 1340 may be improved.

In FIG. 9, the data processing device 1300 may include a flash memory system 1310 and a modem 1320, a central processing unit 1330, a cache system 1333, a RAM 1340 and a user interface 1350 that are connected to one another through a system bus 1360. The flash memory system 1310 may be constituted to be the same with a general memory system and may include a memory controller 1312 and a flash memory 1311. The flash memory system 1310 may store data processed by the central processing unit 1330 or data inputted from the outside. The flash memory system 1310 may be embodied by a solid state disk (SSD). In this case, the data processing device 1300 may stably store huge amounts of data in the flash memory system 1310. Although not illustrated in the drawing, the data processing device 1300 may further include an application chipset, a camera image processor CIS or an input/output device or the like.

Constituent elements constituting the data processing device 1300 may be embodied through one of various types of packages. For example, the constituent elements may be packaged by various types of packages such as PoP (package on package), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP), wafer-level processed stack package (WSP) and mounted.

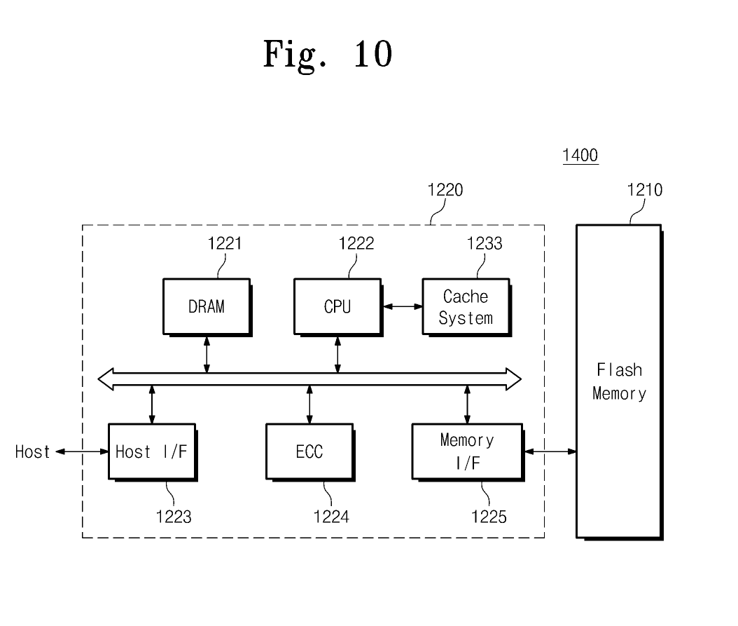

FIG. 10 is a block diagram illustrating an example embodiment of a third application in a memory card. Referring to FIG. 10, a memory card 1400 for supporting a storage capacity of huge amounts of data may include a DRAM 1221 including the antifuse cell array repair device in accordance with some embodiments of the inventive concept. In FIG. 10, if the memory card 1400 applies the DRAM 1221 adopting the antifuse cell array repair device of FIG. 1, a data input/output operation of the DRAM 1221 may be selectively changed. Similarly, even though adopting the spare antifuse cell array, a chip size of the DRAM 1221 is not greatly increased by using the operation control circuit in common. Thus, total performance of memory card 1400 adopting the DRAM 1221 may be improved.

The memory card 1400 includes a memory controller 1220 wholly controlling a data exchange between a host and a flash memory 1210.

In the memory controller 1220, the DRAM 1221 is used as a working memory of a central processing unit 1222. A host interface 1223 performs a data exchange interface between the memory card 1400 and the host. An error correction code block 1224 detects and corrects an error included in data read from the flash memory 1210. The memory interface 1225 performs an interfacing between the flash memory 1210 and the central processing unit 1222. The central processing unit 1222 wholly controls operations that relates to a data exchange of the memory controller 1220. Although not illustrated in the drawing, the memory card 1400 may further include a ROM (not illustrated) storing code data for interfacing with the host.

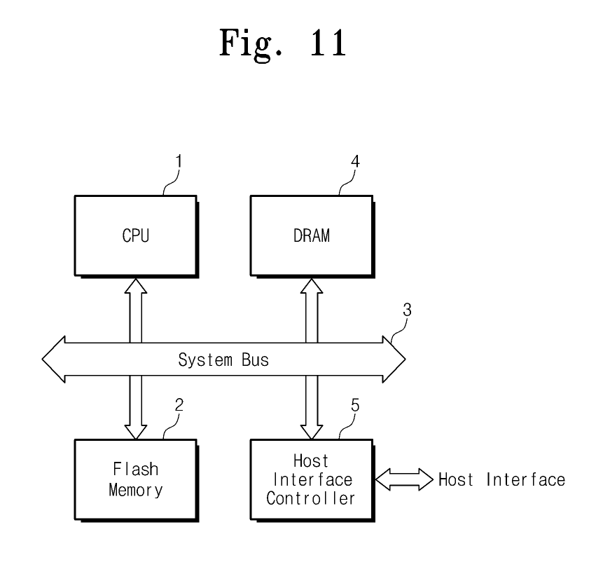

FIG. 11 is a block diagram illustrating an example embodiment of a fourth application in a portable terminal. Referring to FIG. 11, a portable terminal such as PMP, cellular phone or smart phone may include a CUP 1, a flash memory 2, a DRAM 4 and a host interface controller 5 that are connected to one another through a system bus 3.

Since in the case of portable terminal, to compact a terminal may greatly affect the competitive edge of the product, it is important to minimize increases in occupation area of the DRAM 4. In particular, in the case of loading a dual processor for a dual processing operation, setting the DRAM 4 in every processor is avoided. In this case, a DRAM including the spare antifuse cell array in accordance with some embodiments may be adopted while single-handedly having a dual port and a shared memory area. In FIG. 11, if the portable terminal applies the DRAM 4 adopting the antifuse cell array repair device like FIG. 1, a data input/output operation of the DRAM 4 may be selectively changed by programming a spare antifuse cell array. Even though adopting the spare antifuse cell array, a chip size of the DRAM 4 is not greatly increased by using the operation control circuit in common. Thus, total performance of portable terminal adopting the DRAM 4 may be improved.

The example embodiments may be employed in different types of memory systems devices, such as DRAM (including DDR and SDRAM), NAND flash, and NOR flash, RRAM, PRAM, and MRAM, or other memory systems etc.

According to some embodiments, since a circuit constitution embodied for a repair operation of antifuse is relatively simple, an increase of chip size may be effectively suppressed. Also, in the case of newly programming information about an operation of semiconductor memory device in spare antifuses, an operation of the semiconductor memory device may be changed depending on the information programmed in the spare antifuses.

Although a few embodiments have been shown and described, it will be appreciated by those skilled in the art that changes may be made in these embodiments without departing from the principles and spirit of the general inventive concept, the scope of which is defined in the appended claims and their equivalents. Therefore, the above-disclosed subject matter is to be considered illustrative, and not restrictive.

What is claimed is:

1. A semiconductor memory device comprising:
an antifuse cell array including a first set of antifuse cells arranged in a first direction, which each one of the first set of antifuse cells is connected to a corresponding one of first through nth word lines, n is a natural number and greater than 1;
a spare antifuse cell array including a first spare set of antifuse cells arranged in the first direction, which each one of the first spare set of antifuse cells is connected to a corresponding one of first through kth spare word lines, k is a natural number; and
a first operation control circuit configured to program antifuses of the antifuse cell array and the spare antifuse cell array, and configured to read a status of each of the antifuses,
wherein the first operation control circuit is commonly connected to the first set of antifuse cells and the first spare set of antifuse cells.

2. The semiconductor memory device of claim 1, wherein the first operation control circuit comprises a first program circuit to program antifuses selected from the antifuse cell array and the spare antifuse cell array.

3. The semiconductor memory device of claim 2, wherein the first operation control circuit further comprises a first read circuit to read storage information of antifuses programmed by the program circuit.

4. The semiconductor memory device of claim 1, further comprising a fail antifuse cell array to store defect information of the antifuse cell array.

5. The semiconductor memory device of claim 4, wherein the defect information includes information related to at least one of the first through nth word lines.

6. The semiconductor memory device of claim 4, wherein the defect information includes information related to states of the antifuses in the antifuse cell array.

7. The semiconductor memory device of claim 4, when a row address being applied to the semiconductor memory device coincides with information stored in the fail antifuse cell array, further comprising a repair control circuit configured to disable at least one word line of the antifuse cell array and configured to enable at least one spare word line of the spare antifuse cell array.

8. The semiconductor memory device of claim 1, wherein each one of the first through nth word lines and first through kth word lines is disposed along a second direction perpendicular to the first direction, and wherein the first set of antifuse cells and the first spare set of antifuse cells are in a first row in the first direction.

9. The semiconductor memory device of claim 8, further comprising:
a second through mth operation control circuits arranged in the second direction; and
a second through mth set of antifuse cells and a second through mth spare set of antifuse cells arranged in second through mth rows, respectively, in the first direction,
wherein each of the second through mth operation control circuits is commonly connected to a corresponding one of the second through mth set of antifuse cells and a corresponding one of the second through mth spare set of antifuse cells.

10. A semiconductor memory device comprising:
a first antifuse cell array including a first plurality of antifuse cells configured to store data, the first plurality of antifuse cells disposed in a first direction and a second direction perpendicular to the first direction;
a second antifuse cell array including a second plurality of antifuse cells configured to repair a defect data of the first plurality of antifuse cells, the second plurality of antifuse cells disposed in the first direction and the second direction;
a first program circuit configured to program at least one antifuse of each of the first and second plurality of antifuse cells; and
a first read circuit configured to read a status of at least one antifuse of each of the first and second plurality of antifuse cells,
wherein the first program circuit and the first read circuit are commonly connected to at least one cell of the first plurality of antifuse cells and at least one cell of the second plurality of antifuse cells.

11. The semiconductor memory device of claim 10, further comprising:
first through nth word lines connecting cells of the first plurality of antifuse cells, each of the first through nth word lines extending in the second direction;
first through kth word lines connecting cells of the second plurality of antifuse cells, each of the first through kth word lines extending in the second direction.

12. The semiconductor memory device of claim 11, wherein the first program circuit and the first read circuit are further configured to connect to a first set of cells of the first and second plurality of antifuse cells, the first set of cells extending in the first direction.

13. The semiconductor memory device of claim 12, further comprising:
a second through mth program circuits arranged in the second direction, each of the second through mth program circuits commonly connected to a set of cells from the first plurality of antifuse cells and a set of cells from the second plurality of antifuse cells; and
a second through mth read circuits arranged in the second direction, each of the second through mth read circuits is connected to the set of cells from the first plurality of antifuse cells and the set of cells from the second plurality of antifuse cells.

14. The semiconductor memory device of claim 11, further comprising a third antifuse cell array to store defect information of the first antifuse cell array.

15. The semiconductor memory device of claim 14, wherein the defect information includes information related to at least one of the first through nth word lines or states of the antifuses in the first antifuse cell array.

16. An antifuse repair method of a semiconductor memory device comprising:
providing a first antifuse cell array including a first plurality of antifuses arranged in a first direction and sharing an operation control circuit, and the first plurality of antifuses connecting first through nth word lines, each one of the first through nth word lines extending in a second direction perpendicular to the first direction, wherein n is a natural number and greater than 1;
providing a second antifuse cell array including a second plurality of antifuses sharing a spare word line in the second direction and sharing the operation control circuit in the first direction with the first plurality of antifuses;
providing a third antifuse cell array for storing defect information of antifuses of the first antifuse cell array;
comparing a row address being applied to the information stored in the third antifuse cell array; and
inactivating a word line of a failed antifuse of the first plurality of antifuses and activating a spare word line of antifuse of the second plurality of antifuses when the row address coincides with the information stored in the third antifuse cell array.

17. The antifuse repair method of claim 16, further comprising storing information related to an operation of semiconductor memory device in the third antifuse cell array.

18. The antifuse repair method of claim 16, further comprising activating a selected word line of the first antifuse array without activating spare word lines if the row address does not coincide with the information stored in the third antifuse cell array.

19. The antifuse repair method of claim 16, wherein the semiconductor memory device is a dynamic random access memory including a mode register set circuit setting an operation mode for programming an antifuse cell array.

20. The antifuse repair method of claim 16, wherein the stored information in the third antifuse cell array includes information related to a defective word line of the first antifuse cell array.
